(19) United States
(12) Patent Application Publication
(10) Pub. No.: US 2026/0182355 A1
(43) Pub. Date: Jun. 25, 2026

(54) METHOD FOR PRODUCING INTERCONNECTIONS

(71) Applicant: COMMISSARIAT A L'ENERGIE ATOMIQUE ET AUX ENERGIES ALTERNATIVES, Paris (FR)

(72) Inventors: Thibaut CHÊNE, Grenoble Cedex 09 (FR); Fabrice NEMOUCHI, Grenoble Cedex 09 (FR); Roselyne SEGAUD, GRENOBLE Cedex 09 (FR); Thierry CHEVOLLEAU, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/426,631

(22) Filed: Dec. 19, 2025

(30) Foreign Application Priority Data
Dec. 20, 2024 (FR) FR2414892

(51) Int. Cl. H10W 20/45; H10W 20/00; H10W 20/41; H10W 20/42; H10W 20/44

(52) U.S. Cl. CPC H10W 20/455; H10W 20/0633; H10W 20/077; H10W 20/42; H10W 20/435; H10W 20/4405; H10W 20/4446

(57) ABSTRACT

A method of manufacturing an interconnecting level is disclosed. The method includes providing a substrate, forming a first metal layer, forming and patterning a dielectric etch-stop layer to define at least one line pattern with a via opening, forming a second metal layer over the patterned etch-stop layer, defining a via pattern aligned with the via opening, etching the second metal layer to form a via, and etching the first metal layer to form a line connected to the via through the via opening, thereby enabling aligned line-and-via formation using selective etching and a self-aligned dielectric stop.

### TECHNICAL FIELD

The present invention relates to the technical field of interconnections for microelectronics. It has a particularly advantageous application in the formation of vias and of radiofrequency (RF)-compatible interconnecting lines.

### PRIOR ART

The development of microelectronic devices based on “quantum bits” or “qubits”, for example spin qubits or superconductor qubits, requires the manufacture of a specific interconnecting routing. These interconnections are, in particular, with the basis of metal materials, different from copper, generally used in line and via levels associated with the manufacture of field effect transistor-based devices.

Document EP3577700 discloses different methods for producing vias and metal lines adapted to the manufacture of superconductor circuits. In this document, a niobium-and/or aluminium-based via is formed on a first semiconductor metal level, typically niobium-based, by inserting an etching stop layer between the via and the first metal level. This etching stop layer typically makes it possible to best detect the end of etching of the superconductor layer, mainly forming the via. According to this document, this etching stop layer can be aluminium-based and have superconductor properties in a certain temperature range. It thus contributes to the conduction between the via and the underlying superconductor line. According to another option disclosed in document EP3577700, the etching stop layer can be with the basis of a dielectric material. An opening within this etching stop layer is thus provided, in order to connect the via with the underlying superconductor line. This approach requires a plurality of lithography/etching and polishing steps. This increases the dimensional variability, in particular by thickness, of the devices on the scale of a wafer.

Another solution for forming the different line and metal via levels is based on the adaptation of “damascene” type methods. This approach induces other problems, in particular for the etching of the dielectric matrix with a low dielectric constant. An increase of the dielectric constant is typically observed during the etching of the dielectric matrix. The RF compatibility is degraded.

An aim of the present invention is to propose a method for forming interconnecting lines and vias, overcoming, at least partially, the disadvantages mentioned above.

In particular, an aim of the present invention is to propose an alternative method for forming interconnecting lines and vias, having an improved reproducibility.

### SUMMARY

To achieve this aim, according to an embodiment, a method for manufacturing an interconnecting level is provided, comprising at least one line with the basis of a first metal material A and at least one via with the basis of a second metal material B, said method comprising:
a provision of a substrate,
a formation, on the substrate, of a first metal layer with the basis of the first metal material A,
a formation, on the first metal layer, of an etching stop layer with the basis of a dielectric material C having a selectivity S_{A:C} to the etching with respect to the first material A, typically greater than or equal to 5:1,
a structuration of the etching stop layer, through at least one first mask, such that the structured etching stop layer has at least one line pattern, said at least one line pattern comprising at least one via opening,
a formation, on the structured etching stop layer comprising the at least one via opening, of a second metal layer with the basis of the second metal material,
a formation, on the second metal layer, of a second mask defining at least one via pattern in vertical alignment with the at least one via opening,
an etching of the second metal layer, said etching being configured to form the at least one via under the second mask, then
an etching of the first metal layer, said etching being configured to form the at least one line under the at least one line pattern of the structured etching stop layer, said at least one line being connected to said at least one via through the at least one via opening.

Advantageously, the first and second masks are formed on flat layers, respectively on the etching stop layer and on the second metal layer. This makes it possible to limit the dimensional variability linked to the formation of these masks, typically by lithographies.

Advantageously, the etching stop layer is structured, so as to expose the first metal layer outside of the at least one line pattern. This makes it possible to sequence the etchings of the second metal layer and of the first metal layer. The formation of the at least one line from the first metal layer is done at the end of the method. The at least one line is aligned in vertical alignment with the at least one line pattern. The at least one via is aligned in vertical alignment with the at least one via pattern. This avoids resorting to an alignment between the two etchings, contrary to the solution disclosed in document EP3577700. This limits the dimensional variability linked to such an alignment.

The invention also provides, according to a second aspect, a device comprising in a stack along a direction z:
a substrate,
an interconnecting level comprising
at least one connecting line with the basis of a first metal material A,
an etching stop layer with the basis of a dielectric material C having a selectivity
to the etching S_{A:C} with respect to the first material, typically greater than or equal to 5:1,
at least one connecting via with the basis of a second metal material B.

The etching stop layer has at least one line pattern comprising at least one via opening configured to connect the at least one connecting via and the at least one connecting line.

Advantageously, the etching stop layer covers the at least one connecting line along the direction z, without extending outside of said at least one connecting line, projecting along the direction z.

The advantages described above regarding the method apply mutatis mutandis to the device according to the invention.

### BRIEF DESCRIPTION OF THE FIGURES

The aims, objectives, as well as the features and advantages of the invention will best emerge from the detailed description of embodiments of the latter, which are illustrated by the following accompanying drawings, in which:

FIGS. 1 to 10 and 12 to 14 illustrate, in a plane xz, cross-sections representing different steps of the method for manufacturing an interconnecting level according to an embodiment of the present invention.

FIG. 11 schematically illustrates, as a top view, a step of the manufacturing method corresponding to FIG. 10, according to an embodiment of the present invention.

FIGS. 15, 17, 19 schematically illustrate, in a plane xz, cross-sections representing different steps of structuring the etching stop layer according to another embodiment of the present invention.

FIGS. 16 and 18 schematically illustrate, as a top view, the steps of the manufacturing method corresponding to FIGS. 15 and 17, respectively.

FIGS. 20 to 25 schematically represent, in a plane xz, cross-sections representing different steps of structuring the etching stop layer according to another embodiment of the present invention.

The drawings are given as examples and are not limiting of the invention. They constitute principle schematic representations, intended to facilitate the understanding of the invention, and are not necessarily to the scale of practical applications. In particular, the thicknesses and/or the dimensions of the different layers and patterns are not representative of reality. For reasons of clarity, all of the alphanumerical references are not systematically repeated from one figure to another. It is understood that the elements already described and referenced, when they are reproduced in another figure, typically have the same alphanumerical references, even if these are not explicitly mentioned. A person skilled in the art will identify, without difficulties, one same element reproduced in different figures.

### DETAILED DESCRIPTION

Before starting a detailed review of embodiments of the invention, optional features are stated below, which can optionally be used in association or alternatively.

The structuration of the etching stop layer can, in particular, be done in different ways.

According to an example, the structuring of the etching stop layer comprises the following substeps:
a formation of the first mask on the etching stop layer, said first mask directly defining the at least one line pattern comprising the at least one via opening,
a partial removal of the etching stop layer, only at zones of the etching stop layer not covered by the first mask, so as to expose the first metal layer outside of the zones covered by the first mask,
a removal of the first mask.

The formation of the first mask is done, in this case, on the etching stop layer, and covers the parts of the etching stop layer, which will be preserved: the first mask therefore “directly” defines the at least one line pattern comprising the at least one via opening. The at least one line pattern is located under the first mask, in vertical alignment with the first mask.

According to an example, the formation of the first mask is done by double lithography. This makes it possible to obtain patterns resolved beyond the performance of the lithography equipment.

According to an example, the structuration of the etching stop layer comprises the following substeps:
before formation of the etching stop layer, a formation of the first mask on the first metal layer, said first mask indirectly defining the at least one line pattern comprising the at least one via opening,
the formation of the etching stop layer by selective deposition of the dielectric material on zones of the first metal layer not covered by the first mask,
a removal of the first mask.

The formation of the first mask is done, in this case, before the formation of the etching stop layer, and covers the parts of the first metal layer, which will not be covered by the etching stop layer: the first mask therefore “indirectly” defines the at least one line pattern comprising the at least one via opening. The at least one line pattern is located on the parts of the first metal layer not covered by the first mask.

According to an example, the selective deposition of the dielectric layer is done atomic layer deposition (ALD). According to another example, the selective deposition of the dielectric material is done by chemical vapour deposition (CVD).

According to an example, the at least one via pattern has a critical dimension CD₂, taken along an axis x, greater than a dimension CDₒₚₑₙ of the at least one via opening taken along the axis x. This makes it possible to introduce a certain tolerance in the alignment between the first and second masks, in particular for the definition of the first and second masks by lithography. The second mask can thus partially cover the edges of the via opening of the first mask, projecting along a stacking direction z. According to another example, the at least one via pattern has a critical dimension CD₂, taken along an axis x, substantially equal to a dimension CDₒₚₑₙ of the at least one via opening taken along the axis x.

According to an example, the at least one via pattern has a critical dimension CD₂, taken along an axis x, less than a dimension CD₁ of the at least one line pattern taken along the axis x.

According to an example, the etching of the second metal layer and the etching of the first metal layer are sequenced along one single and same sequences of etchings. This sequence of etchings can comprise several substeps with different plasma conditions, for example.

According to an example, the etching of the second metal layer and the etching of the first metal layer are done by one single and same etching, during one single and same step. The etching conditions remain substantially identical during the etching of the second and first metal layers. This makes it possible to reduce the duration and/or the costs of the method.

According to an example, the first metal material A and/or the second metal material B are with the basis of at least one from among: TiN, TaN, W, Ru, Ti, Ta, V3SI, CoSi₂, Nb₃Ge, Al, NbN, and their alloys.

According to an example, the first metal material A and the second metal material B are with the basis of the same material.

According to an example, the first metal material A and/or the second metal material B are different from copper.

According to an example, the etching stop layer with the basis of a dielectric material C has a selectivity S_{A:C} to the etching with respect to the first material A, greater than or equal to 5:1.

According to an example, the etching stop layer is with the basis of a dielectric material C taken from among: SiO₂, TiO₂, HfO₂, HfN, ZrN, SiN, SiCN. This makes it possible to obtain a selectivity S_{A:C} to the etching between the first metal material A and the dielectric material C, greater than or equal to 5:1. The etching speed of the etching stop layer is at least five times less than the etching speed of the first and second metal layers. According to an example, the selectivity S_{A:B} to the etching between the first metal material A and the dielectric material C is greater than 10:1.

According to an example, the at least one connecting via has a critical dimension CDᵥᵢₐ, taken along an axis x, greater than a dimension CDₒₚₑₙ of the at least one via opening taken along the axis x, and less than a dimension CDₗᵢₙₑ of the at least one connecting line taken along the axis x, such that the etching stop layer is partially inserted between the at least one connecting via and the at least one connecting line.

According to another example, the at least one connecting via has a critical dimension CDᵥᵢₐ, taken along an axis x, substantially equal to a dimension CDₗᵢₙₑ of the at least one connecting line taken along the axis x, such that the etching stop layer is sandwiched between the at least one connecting via and the at least one connecting line.

According to an example, the at least one connecting line has a critical dimension CDₗᵢₙₑ, taken along an axis x, substantially equal to a dimension CD₁, taken along the axis x, of the at least one line pattern of the etching stop layer.

According to an example, the at least one connecting line has a critical dimension CDₗᵢₙₑ, taken along an axis x, substantially equal to a critical dimension CDᵥᵢₐ, taken along the axis x, of the at least one connecting via.

Unless incompatible, it is understood that all of the optional features above and/or the indicated variants can be combined, so as to form an embodiment which is not necessarily illustrated or described. Such an embodiment is clearly not excluded from the invention.

It is specified that, in the scope of the present invention, the terms “on”, “surmounts”, “covers”, “underlying” “opposite” and their equivalents do not necessarily mean, “in contact with”. Thus, for example, the deposition or the application of a first layer on a second layer, does not compulsorily mean that the two layers are directly in contact with one another, but means that the first layer covers, at least partially, the second layer, by being either directly in contact with it, or by being separated from it by at least one other layer or at least one other element.

By a substrate, a film, a layer, “with the basis” of a material A, this means a substrate, a film, a layer comprising this material A only, or this material A and optionally other materials, for example, doping elements or alloy elements. Thus, a silicon nitride SiN-based spacer can, for example, comprise non-stoichiometric silicon nitride (SiN), or stoichiometric silicon nitride (Si₃N₄), or also a silicon oxynitride (SiON).

The word “dielectric” qualifies a material, the electrical conductivity of which is sufficiently low in the given application to serve as an insulator. In the present invention, a dielectric material preferably has a dielectric constant less than 20, and preferably, less than 10.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method. The etchings of the first and second metal layers can, in particular, be sequenced or be considered as forming part of one single and same etching step.

By “selective etching with respect to” or “etching having a selectivity with respect to”, this means an etching configured to remove a material A or a layer A with respect to a material B or a layer B, and having an etching speed of the material A, greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A preferably orthonormal system, comprising the axes x, y, z is represented in the accompanying figures.

In the present patent application, thickness will preferably be referred to for a layer or a film, and height will preferably be referred to for a device or a structure. The thickness is taken along a direction normal to the main extension plane of the layer or of the film. Thus, a metal layer typically has a thickness along z. A via formed from such a metal layer has a height along z. The relative terms “on”, “surmounts”, “upper”, “under”, “underlying”, “lower” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another element means that these two elements are both located on one same line perpendicular to a plane into which a lower or upper face of a substrate mainly extends, i.e. on one same line oriented vertically in the figures, in a cross-section.

The terms “substantially”, “around”, “about” mean plus or minus 10%, and preferably, plus or minus 5%. Moreover, the term “between . . . and . . . ” and equivalents mean that the limits are inclusive, unless mentioned otherwise.

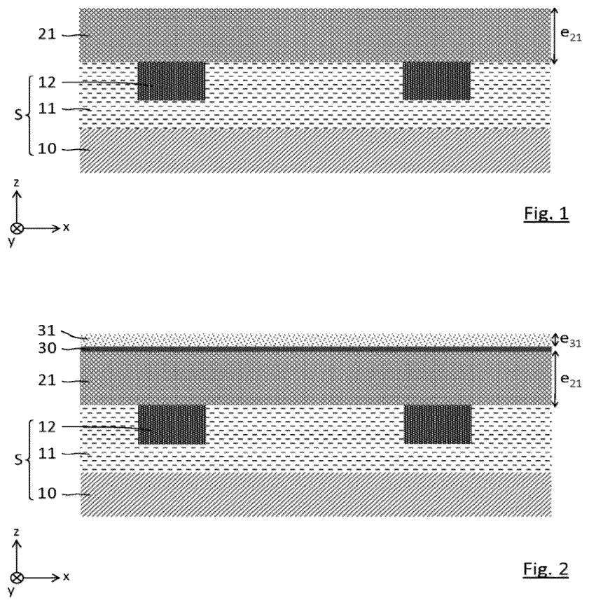

The step of manufacturing an interconnecting level according to a first embodiment of the invention are illustrated in FIGS. 1 to 14.

As illustrated in FIG. 1, the method comprises a provision of a substrate S typically comprising a silicon-based support layer 10 carrying components, for example, spin qubit transistors or superconductor qubits. The substrate S can also comprise connecting pads 12 integrated in a first silicon oxide-based layer 11, surmounting the support layer 10. An aim of the method according to the invention is to form lines connecting the pads 12, and vias surmounting and connecting these lines.

A first metal layer 21 is first formed on the substrate S. The first metal layer 21 can be formed from one or more materials, from among Ti, TiN, Ta, TaN, W, Ru, V₃Si, CoSi₂, Nb₃Ge, Al, NbN. The first metal layer 21 can, in particular, be formed by physical vapour deposition (PVD). This metal layer 21 typically has a thickness e₂₁ of around a few tens of nanometres, for example, around 40nm. After deposition, the first metal layer 21 is typically planarised, for example, conventionally by chemical-mechanical polishing (CMP).

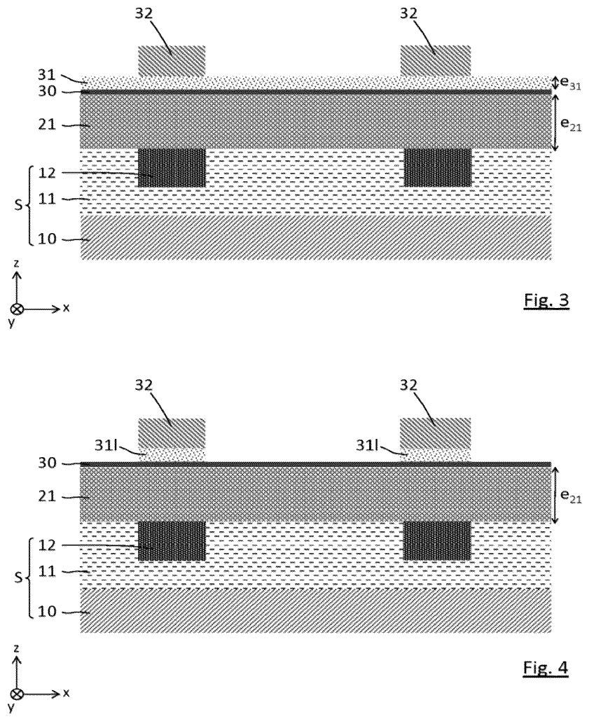

As illustrated in FIG. 2, an etching stop layer 30 is then directly formed on the first metal layer 21. This etching stop layer 30 typically has a thickness of around a few nanometres, for example, less than 5nm. It is preferably with the basis of a dielectric taken from among SiO₂, TiO₂, HfO₂, HfN, ZrN, SiN, SiCN. The formation of the etching stop layer 30 can, in particular, be done by one of the following techniques: physical vapour deposition (PVD), chemical vapour deposition (CVD), plasma enhanced chemical vapour deposition (PECVD), atomic layer deposition (ALD), plasma enhanced atomic layer deposition (PEALD).

A so-called colouring layer 31, intended to form a first etching mask, is deposited on the etching stop layer 30. This colouring layer 31 is, for example, SiON-based. It typically has a thickness e₃₁ of around a few nanometres to a few tens of nanometres, for example, around 5 nm to 10 nm. The colouring layer 31 is then structured by lithography/etching, so as to form the first etching mask. This structuration can be done by single lithography, for example, in extreme UV insolation, or by double lithography, known as “double patterning”.

FIGS. 3 to 8 illustrate a structuration of the colouring layer 31 by “double patterning”.

As illustrated in FIG. 3, a first lithography can be done, so as to define line patterns 32 in a first photosensitive resin layer, preferably in vertical alignment with the pads 12.

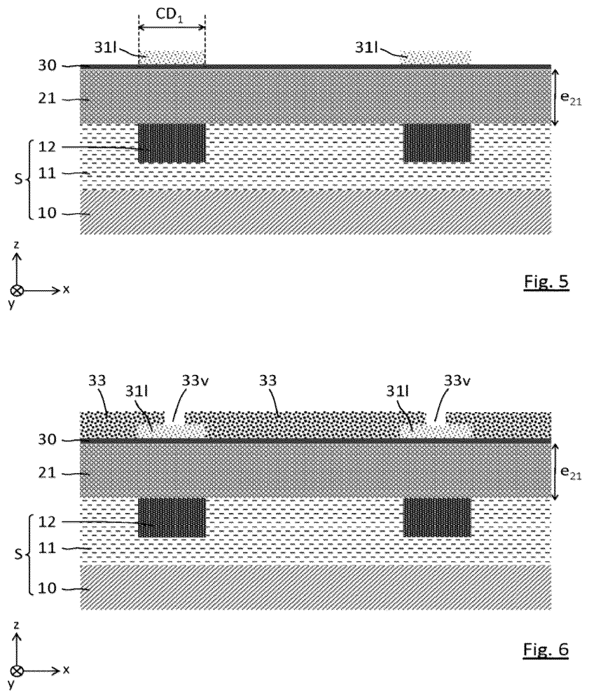

As illustrated in FIG. 4, a first etching can then be done, so as to transfer the line patterns 32 in the colouring layer 31. The colouring layer is thus partially structured. This first partial structuration makes it possible to obtain line patterns 31l in the colouring layer.

As illustrated in FIG. 5, the line patterns 32 of the first resin layer are then removed, for example, by oxygen-based plasma, so as to re-expose the line patterns 31l of the partially structured colouring layer. In the case of structuration by “double patterning”, the line patterns 31l typically have a dimension CD₁, along x, of between 70 nm and 100 nm, for example, around 80 nm.

As illustrated in FIG. 6, a second lithography can be done, so as to define via opening patterns 33v in a second photosensitive resin layer 33, on the line patterns 31l of the partially structured colouring layer.

As illustrated in FIG. 7, a second etching can be done, so as to complete the structuration of the colouring layer. The via opening layers 33v are transferred in the colouring layer. This second structuration makes it possible to obtain via opening patterns 31v within the line patterns 31l of the colouring layer.

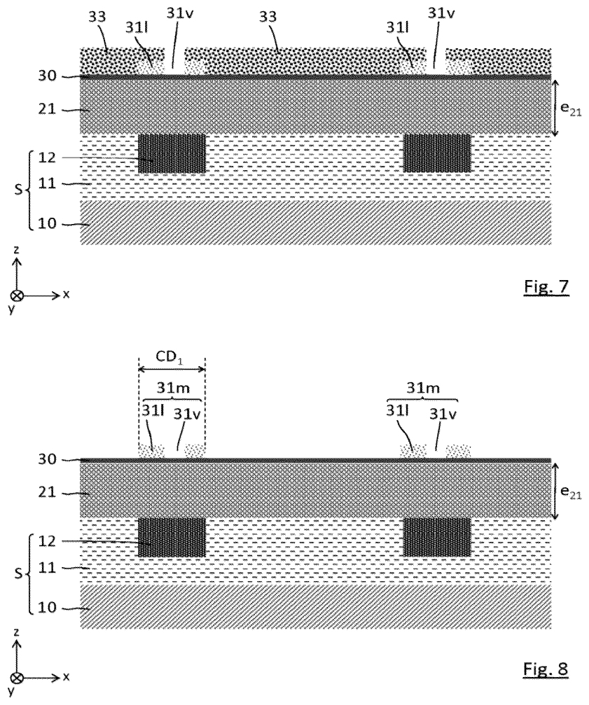

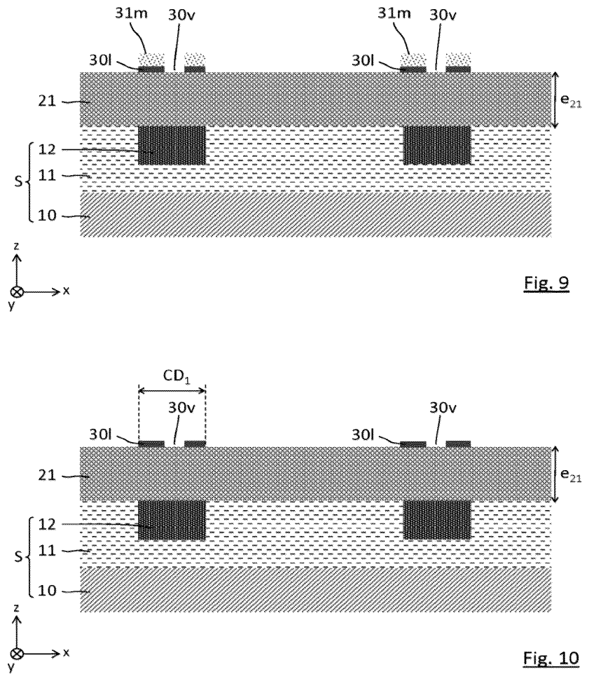

As illustrated in FIG. 8, after removal of the second resin layer 33, a first etching mask 31m comprising line patterns 31l and of the via opening patterns 31v is formed on the etching stop layer 30.

The first etching mask is not necessarily with the basis of a colouring layer, nor necessarily done by “double patterning”. When the first etching mask is done by single lithography, the dimension CD₁ of the line patterns 31l is typically between 100 nm and 200 nm, for example, around 130 nm. When the first etching mask is produced by extreme UV lithography, the dimension CD₁ of the line patterns 31l is typically between 20 nm and 50 nm, for example, around 26 nm. This first etching mask 31m is, in this case, used to directly transfer the line patterns 31l and the via opening patterns 31v into the etching stop layer 30.

As illustrated in FIG. 9, an anisotropic etching of the etching stop layer 30, along z, is done to form the line patterns 30l under the line patterns 31l, and the via opening patterns 30v under the via opening patterns 31v. This etching can have a chlorine-or fluorine-based halogenated etching chemistry, according to the type of mask 31m and the nature of the etching stop layer 30. For a hafnium-based etching stop layer 30, the etching can be done from a BCl₃ etching chemistry. For a silicon-based etching stop layer 30, the etching can be done from a fluorocarbon etching chemistry, for example, CF₄.

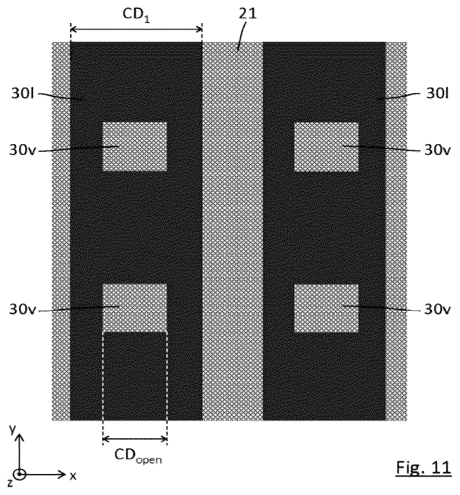

As illustrated in FIGS. 10 and 11, as a transverse view and as a top view respectively, after removal of the first etching mask 31m, a structured etching stop layer, comprising line patterns 30l and via opening patterns 30v, is obtained on the first metal layer 21. The line patterns 30l typically have the dimension CD₁ along x, and the via opening patterns 30v typically have the dimension CDₒₚₑₙ along x. When the first etching mask is produced by single lithography or by “double patterning”, the dimension CDₒₚₑₙ of the via opening patterns 30v is typically between 30 nm and 70 nm, for example, around 50 nm. When the first etching mask is produced by extreme UV lithography, the dimension CDₒₚₑₙ of the via opening patterns 30v can be between 8 nm and 20 nm, for example, around 10 nm.

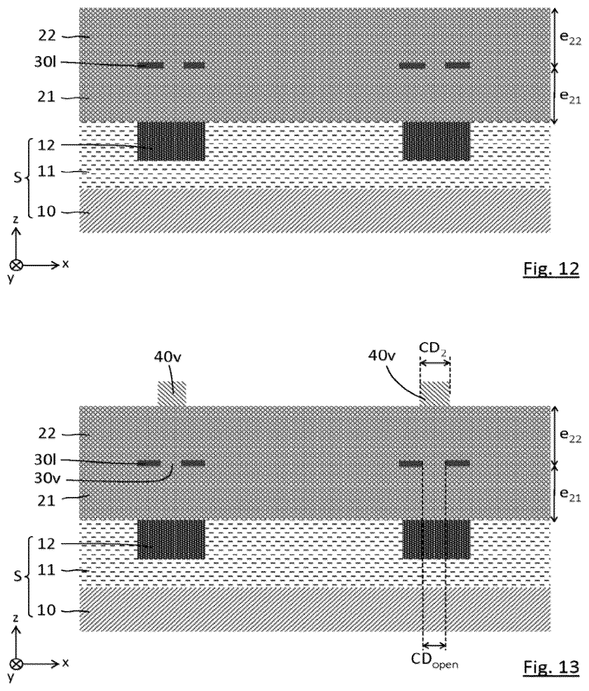

As illustrated in FIG. 12, after structuration of the etching stop layer, a second metal layer 22, typically with the basis of the same metal(s) as the first metal layer 21, is then formed on the first metal layer 21 and on the structured etching stop layer 30l. This metal layer 22 typically has a thickness e₂₂ of around a few tens of nanometres, for example, around 40nm. The thicknesses e₂₁ and e₂₂ are preferably chosen, such that the total thickness e₂₁ +e₂₂ of the metal layers 21, 22 is between 90 nm and 110 nm. After deposition, the second metal layer 22 is typically planarised, for example, conventionally by chemical-mechanical polishing (CMP).

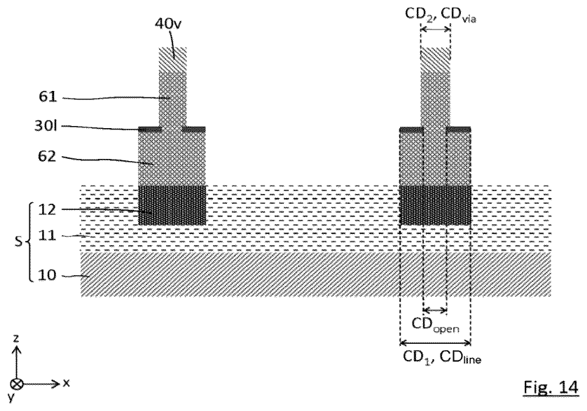

As illustrated in FIG. 13, a second etching mask 40 comprising via patterns 40v is formed on the second metal layer 22. This second etching mask 40 is preferably with the basis of organic layers, for example, in the form of a known stack called “trilayer”, typically comprising an organic planarisation layer, an antireflection layer and a photosensitive resin layer.

The via patterns 40v of this second etching mask 40 are aligned with the via opening patterns 30v of the etching stop layer, such that the via patterns 40v are in vertical alignment with the via opening patterns 30v. The via patterns 40v typically have a slightly greater dimension CD₂ along x, for example, 10% greater, than the dimension CDₒₚₑₙ along x of the via patterns 30v. This facilitates the alignment of the patterns 40v, 30v together. A certain tolerance on the alignment accuracy is thus obtained.

As illustrated in FIG. 14, the first and second metal layers 21, 22 are then etched over their entire thickness, along z, outside of the via patterns 40v. The second metal layer 22 is first etched to form the connecting vias 61, then the first metal layer 21 is etched to form the connecting lines 62. The etchings of the first and second metal layers 21, 22 are preferably sequenced. According to an option, in particular, when the first and second metal layers 21, 22 are of an identical nature, the etchings of these metal layers 21, 22 are done in one single and same step, with the same etching chemistry.

The etchings are, in this case, chosen so as to selectively etch the first and second metal layers 21, 22 with respect to the material of the etching stop layer. In particular, the etching selectivity S_{A:C}, i.e. the ratio between the etching speed of the metal material(s) over the etching speed of the material of the etching stop layer, is greater than or equal to 5:1, preferably greater than or equal to 10:1.

The etching(s) of the metal material(s) can be done in chlorinated chemistry. In this case, a good selectivity is obtained with respect to the etching stop layer. In particular, when this is HfO₂- or SiO₂-based, the etching speed of the etching stop layer is less than 20 nm/min. Alternatively, the etching(s) of the metal material(s) can be done in fluorinated or fluorocarbon chemistry. In this case, it is preferable to avoid SiN and SiO₂ as a dielectric material of the etching stop layer.

After etching, metal vias 61 having a critical dimension CDᵥᵢₐ along x are obtained. The critical dimension CDᵥᵢₐ along x is substantially equal to the dimension CD₂ of the via patterns 40v. Metal lines 62 having a critical dimension CDₗᵢₙₑ along x are obtained. The critical dimension CDₗᵢₙₑ along x is substantially equal to the dimension CD₁ of the line patterns 30l. The metal vias 61 are connected to the metal lines 62 integrally with the metal material through the via openings 30v.

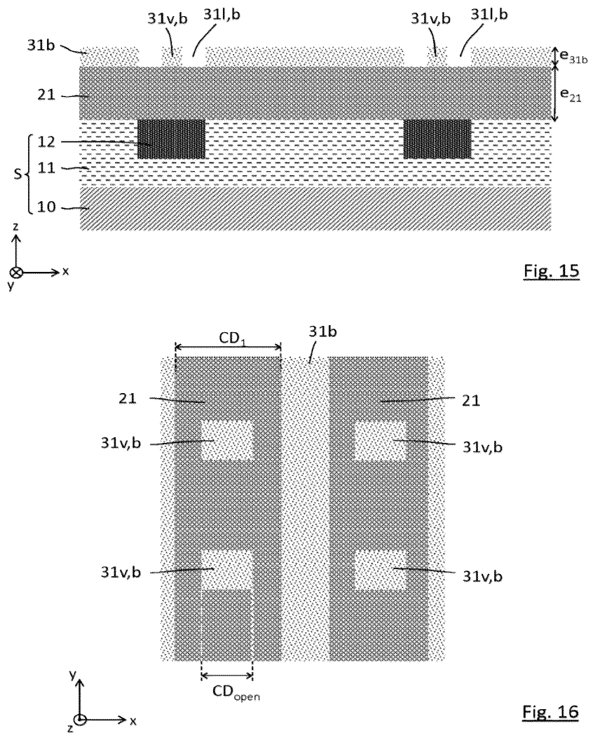

FIGS. 15 to 19 illustrate a structuration of the etching stop layer according to another embodiment of the invention.

As illustrated in FIGS. 15, 16, a first resin-based mask 31b with inverted polarity is first formed directly on the first metal layer 21. It comprises pads 31v,b of diₒₚₑₙion CDₒₚₑₙ along x, defining the via openings, and openings 31l,b of dimension CD₁ along x, defining the line patterns.

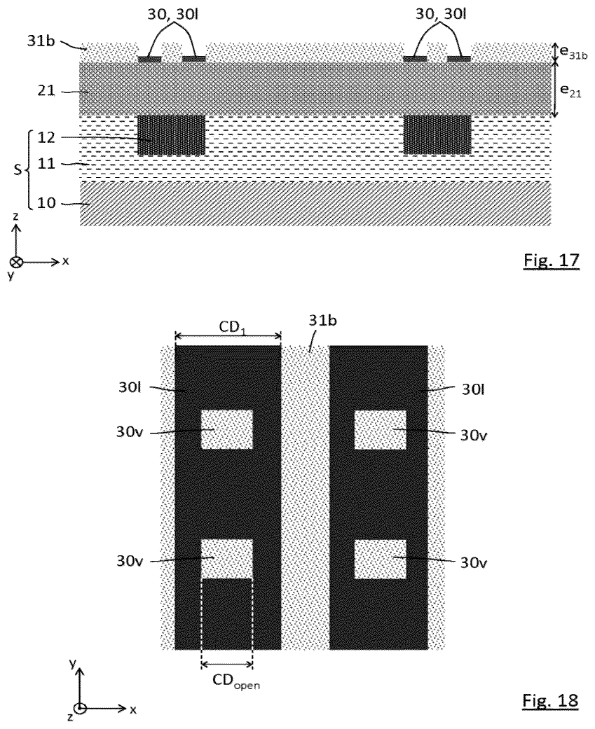

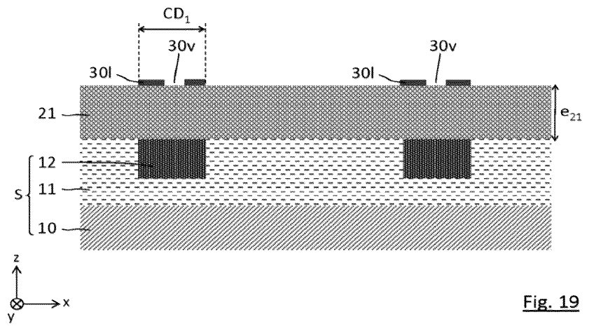

As illustrated in FIGS. 17, 18, a selective deposition of the dielectric material B is done in the openings 31l,b, on the first metal layer 21. This deposition can typically be done by atomic layer deposition (ALD), This makes it possible to form a directly structured etching stop layer 30l. The structuration of the etching stop layer by lithography/etching is thus avoided. This makes it possible to preserve the surface of the first metal layer 21, in particular, under the pads 31v,b. The quality of the interface subsequently obtained between the via and the underlying line is thus preserved.

As illustrated in FIG. 19, the first resin-based mask 31b is then removed, typically by O₂/N₂ plasma. A directly structured etching stop layer 30 is thus obtained. The subsequent steps of forming the vias and the lines are identical to those described above.

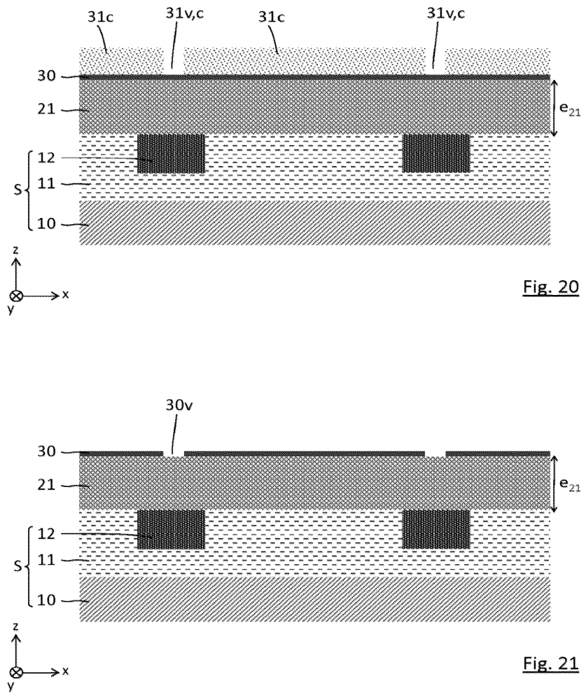

FIGS. 20 to 25 illustrate a structuration of the etching stop layer according to another embodiment of the invention.

As illustrated in FIG. 20, a resin-based mask 31c is formed on the etching stop layer 30. It only comprises openings 31v,b of dimension CDₒₚₑₙ along x, defining the via openings.

As illustrated in FIG. 21, an etching through the openings 31v,b makes it possible to form the via openings 30v in the etching stop layer 30. The etching stop layer 30 is, in this case, partially structured and only comprises, at this stage, the via openings 30v.

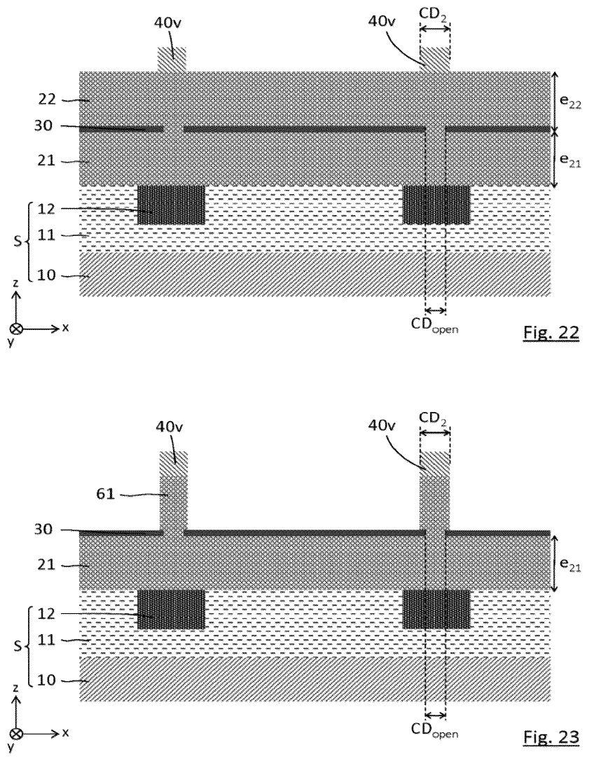

As illustrated in FIG. 22, the second metal layer 22 is then formed on the partially structured etching stop layer, and in the via openings 30v. An etching mask comprising via patterns 40v is formed on the second metal layer 22, as above. The via patterns 40v have a dimension CD₂.

As illustrated in FIG. 23, the second metal layer 22 is then etched, stopping on the etching stop layer, in order to form the connecting vias 61.

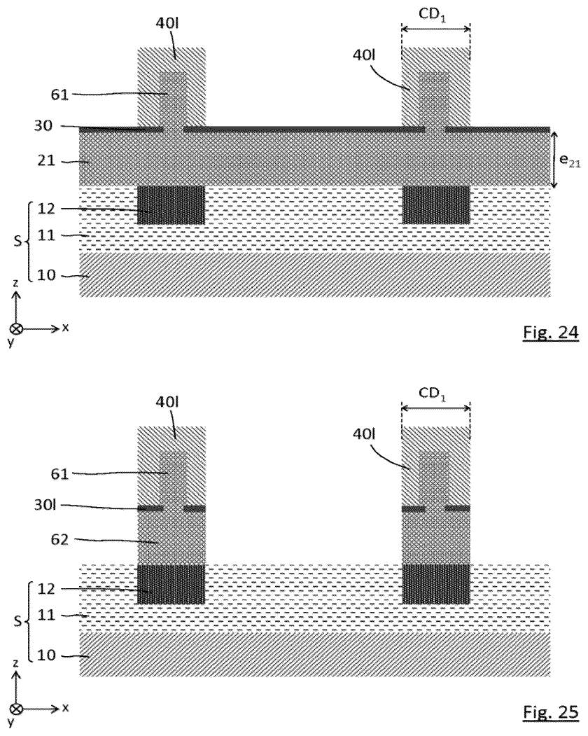

As illustrated in FIG. 24, an etching mask comprising line patterns 40l is formed on and around the connecting vias 61, preferably in vertical alignment with the connecting pads 12. The line patterns 40l have a dimension CD₁.

As illustrated in FIG. 25, one or more etchings are then done to remove the etching stop layer 30, then the first metal layer 21 outside of the zones covered by the line patterns 40l. Connecting lines 62 are thus formed. This variant makes it possible to consider pairs of materials A, C having a lower selectivity to the etching S_{A:C}.

In view of the description above, it clearly appears that the method and the device proposed offer a particularly effective and versatile solution to form via-and metal line-based interconnecting levels, adapted to the manufacture of radiofrequency and/or superconductor circuits.

The invention is not limited to the embodiments described above.

1-14. (canceled)

15. A method of manufacturing an interconnecting level comprising at least one line formed from a first metal material and at least one via formed from a second metal material, the method comprising:
providing a substrate;
forming a first metal layer on the substrate, the first metal layer comprising the first metal material;
forming an etch-stop layer on the first metal layer, the etch-stop layer comprising a dielectric material having a selectivity to etching with respect to the first metal material;
patterning the etch-stop layer through at least one first mask such that the patterned etch-stop layer defines at least one line pattern comprising at least one via opening;
forming a second metal layer on the patterned etch-stop layer, the second metal layer comprising the second metal material;
forming a second mask on the second metal layer defining at least one via pattern in vertical alignment with the at least one via opening;
etching the second metal layer to form the at least one via beneath the second mask; and
etching the first metal layer to form the at least one line beneath the at least one line pattern of the patterned etch-stop layer, the at least one line being connected to the at least one via through the at least one via opening.

16. The method of claim 15, wherein patterning the etch-stop layer comprises:
forming the first mask on the etch-stop layer, the first mask directly defining the at least one line pattern comprising the at least one via opening;
partially removing the etch-stop layer only in regions not covered by the first mask to expose the first metal layer outside regions covered by the first mask; and
removing the first mask.

17. The method of claim 16, wherein forming the first mask is performed by double lithography.

18. The method of claim 15, wherein patterning the etch-stop layer comprises:
prior to forming the etch-stop layer, forming the first mask on the first metal layer, the first mask indirectly defining the at least one line pattern comprising the at least one via opening;
forming the etch-stop layer by selective deposition of the dielectric material on regions of the first metal layer not covered by the first mask; and
removing the first mask.

19. The method of claim 18, wherein the selective deposition is performed by atomic layer deposition or by chemical vapor deposition.

20. The method of claim 15, wherein the at least one via pattern has a critical dimension along an x-axis greater than a dimension of the at least one via opening along the x-axis and less than a dimension of the at least one line pattern along the x-axis.

21. The method of claim 15, wherein etching the second metal layer and etching the first metal layer are sequenced within a single sequence of etching steps.

22. The method of claim 15, wherein the first metal material and/or the second metal material comprises at least one of TiN, TaN, W, Ru, Ti, Ta, V₃Si, CoSi₂, Nb₃Ge, Al, or NbN.

23. The method of claim 15, wherein the first metal material and the second metal material comprise a same material.

24. The method of claim 15, wherein the etch-stop layer comprises a dielectric material selected from SiO2, TiO2, HfO2, HfN, ZrN, SiN, and SiCN.

25. An interconnect device comprising, in a vertical stack along a z-direction:
a substrate; and
an interconnecting level comprising:
at least one connecting line comprising a first metal material;
an etch-stop layer comprising a second dielectric material having a selectivity to etching with respect to the first metal material; and
at least one connecting via comprising a second metal material;
wherein the etch-stop layer includes at least one line pattern comprising at least one via opening configured to connect the at least one connecting via to the at least one connecting line, and
wherein the etch-stop layer covers the at least one connecting line along the z-direction without extending outside the at least one connecting line when projected along the z-direction.

26. The interconnect device of claim 25, wherein the at least one connecting via has a critical dimension along an x-axis greater than a dimension of the at least one via opening along the x-axis and less than a dimension of the at least one connecting line along the x-axis, such that the etch-stop layer is partially inserted between the at least one connecting via and the at least one connecting line.

27. The interconnect device of claim 25, wherein the at least one connecting line has a critical dimension along an x-axis substantially equal to a critical dimension along the x-axis of the at least one connecting via.

28. The interconnect device of claim 25, wherein the first metal material comprises at least one of TiN, TaN, W, Ru, Ti, Ta, V₃Si, CoSi₂, Nb₃Ge, Al, NbN, or alloys thereof.
